(19) United States
(12) Patent Application Publication
(10) Pub. No.: US 2024/0237510 A1
(43) Pub. Date: Jul. 11, 2024

(54) ORGANIC LIGHT-EMITTING DIODE STRUCTURE AND DISPLAY DEVICE

(71) Applicant: BOE Technology Group Co., Ltd., Beijing (CN)

(72) Inventors: Rongrong GAO, Beijing (CN); Lei CHEN, Beijing (CN)

(21) Appl. No.: 17/913,791

(22) PCT Filed: Nov. 9, 2021
(86) PCT No.: PCT/CN2021/129588

§ 371 Date: Sep. 22, 2022

(30) Foreign Application Priority Data
Apr. 6, 2021 (CN) 202110367717.X

(51) Int. Cl. H10K 85/60; H10K 50/11; H10K 50/16; H10K 101/40; H10K 101/60

(52) U.S. Cl. CPC H10K 85/615; H10K 85/624; H10K 85/626; H10K 85/654; H10K 85/6574; H10K 50/11; H10K 50/16; H10K 2101/40; H10K 2101/60

(57) ABSTRACT

The present disclosure provides an organic light-emitting diode structure and a display device. In the organic light-emitting diode structure, the light-emitting layer, the hole blocking layer and the electron blocking layer satisfy the following conditions: T1 (HBL)>T1 (Host); T1 (EBL)>T1 (Host); T1 (Dopant)>T1 (Host); S1 (Host)>S1 (Dopant); wherein T1 (HBL) is the lowest triplet energy of the hole blocking layer material, T1 (Host) is the lowest triplet energy of the host material, T1 (EBL) is the lowest triplet energy of the electron blocking layer material, T1 (Dopant) is the lowest triplet energy of the guest material, S1 (Host) is the lowest singlet energy of the host material, and S1 (Dopant) is the lowest singlet energy of the guest material.

### CROSS-REFERENCE TO RELATED APPLICATION

This application claims a priority to Chinese Patent Application No. 202110367717.X filed on Apr. 6, 2021, the disclosures of which are incorporated in their entirety by reference herein.

### TECHNICAL FIELD

The present disclosure relates to the field of display technology, and in particular, to an organic light-emitting diode structure and a display device.

### BACKGROUND

As a new type of display technology, the Organic Light-Emitting Diode (OLED) has gradually attracted more attention. It has become an extremely popular and dominant display product on the market due to its characteristics of active luminescence, high brightness, high resolution, wide viewing angle, fast response speed, low energy consumption and flexibility.

### SUMMARY

In the first aspect, an embodiment of the present disclosure provides an organic light-emitting diode structure, including a cathode, an electron transport layer, a hole blocking layer, a light-emitting layer, an electron blocking layer, a hole transport layer and an anode that are stacked in sequence, wherein the light-emitting layer includes a host material and an guest material.

In which the host material has a structure of:

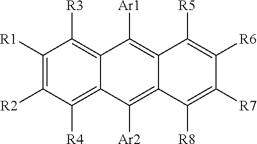

in which:
R1, R2, R3, R4, R5, R6, R7 and R8 are each independently selected from: hydrogen atom, deuterium atom, substituted or unsubstituted aryl having 6 to 60 carbon atoms, substituted or unsubstituted heteroaryl having 6 to 60 carbon atoms, substituted or unsubstituted alkyl having 1 to 50 carbon atoms, substituted or unsubstituted cycloalkyl having 1 to 50 carbon atoms, substituted or unsubstituted alkoxy having 1 to 50 carbon atoms, substituted or unsubstituted aralkyl having 6 to 50 carbon atoms, substituted or unsubstituted aryloxy having 5 to 50 ring atoms, substituted or unsubstituted arylthio having 5 to 50 ring atoms, and substituted or unsubstituted alkoxycarbonyl having 1 to 50 carbon atoms.

Ar1 is substituted or unsubstituted aryl.

Ar2 is selected from any one of the following:

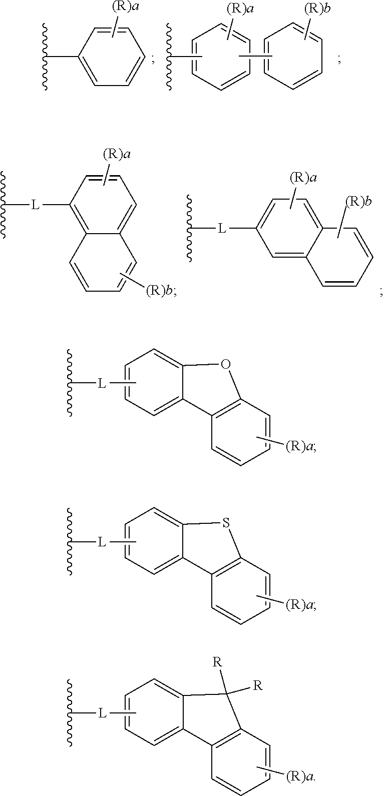

In which, L is a single bond, or substituted or unsubstituted aryl.

R is a substituted or unsubstituted aryl group, a substituted or unsubstituted heteroaryl group, and a plurality of Rs are the same or different:
a is an integer from 0 to 5, and b is an integer from 0 to 5.
the light-emitting layer, the hole blocking layer and the electron blocking layer satisfy the following conditions:

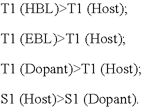

An electron blocking layer material and a hole transport layer material include aromatic amine materials or carbazole materials, a hole mobility of the hole transport layer ranges from 10⁻⁴ to 10⁻⁶ cm² V⁻¹ s⁻¹, a hole mobility of the electron blocking layer ranges from 10⁻⁴ to 10⁻⁷ cm² V⁻¹ s⁻¹.

In which, T1 (HBL) is the lowest triplet energy of the hole blocking layer material, T1 (Host) is the lowest triplet energy of the host material, T1 (EBL) is the lowest triplet energy of the electron blocking layer material, T1 (Dopant) is the lowest triplet energy of the guest material, S1 (Host) is the lowest singlet energy of the host material, and S1 (Dopant) is the lowest singlet energy of the guest material.

Optionally, the hole blocking layer and the electron transport layer satisfy the following conditions:

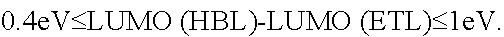

In which, LUMO (HBL) is the lowest unoccupied molecular orbital of the hole blocking layer material, and LUMO (ETL) is the lowest unoccupied molecular orbital of the electron transport layer material.

Optionally, the hole transport layer and the electron blocking layer satisfy the following conditions:

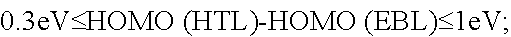

In which, HOMO (HTL) is the highest occupied molecular orbital of the hole transport layer, and HOMO (EBL) is the highest occupied molecular orbital of the electron blocking layer.

Optionally, an electron mobility of the hole blocking layer ranges from 10⁻⁷ to 10⁻⁹ cm² V⁻¹ s⁻¹, and an electron mobility of the electron transport layer ranges from 10⁻⁵ to 10⁻⁷ cm² V⁻¹ s⁻¹.

An electron mobility of the host material of the light-emitting layer ranges from 10⁻⁵ to 10⁻⁸ cm² V⁻¹ s⁻¹, and a hole mobility ranges from 10⁻⁸ to 10⁻¹² cm² V⁻¹ s⁻¹.

Optionally, two adjacent substituents of R1, R2, R3, R4, R5, R6, R7 and R8 are bonded to form a ring.

Optionally, two adjacent Rs are bonded to form a ring.

Optionally, the host material is selected from:

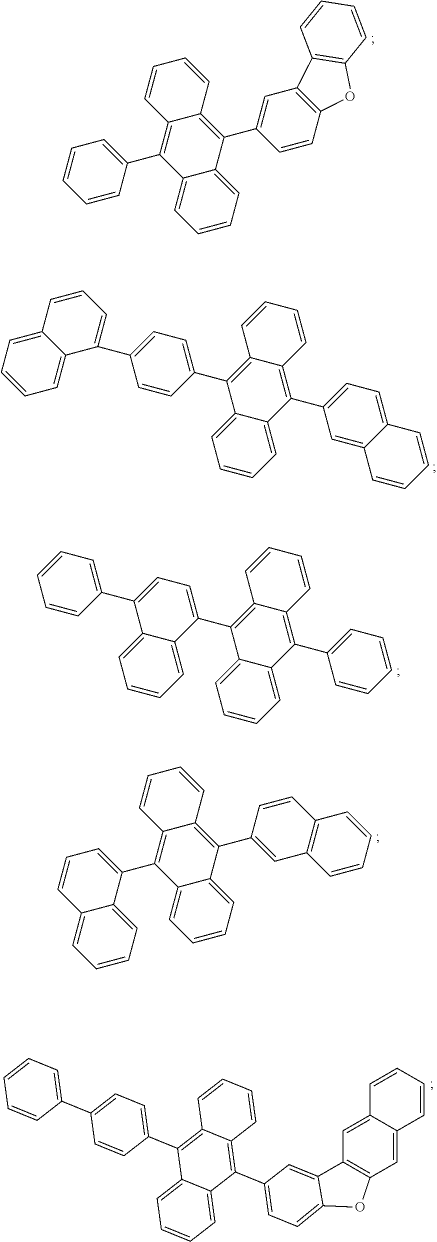

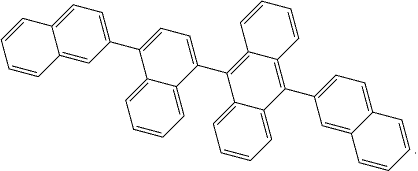 [SMILES: c1ccc2cc(-c3ccc(-c4c5ccccc5c(-c5ccc6ccccc6c5)c5ccccc45)c4ccccc34)ccc2c1]

Optionally, the electron transport layer material has a structure of:

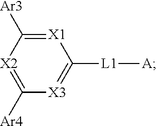

in which, X1, X2 and X3 are C or N, and at least one of X1, X2 and X3 is N;
L1 is a single bond, substituted or unsubstituted C6 to C60 arylene;
Ar3 and Ar4 are substituted or unsubstituted C6 to C60 aryl;
Ar3 and Ar4 are substituted or unsubstituted C2 to C60 heteroaryl containing at least one of O, N, Si and S;
Ar3 and Ar4 are the same or different;
a structure of A is selected from any one of the following:

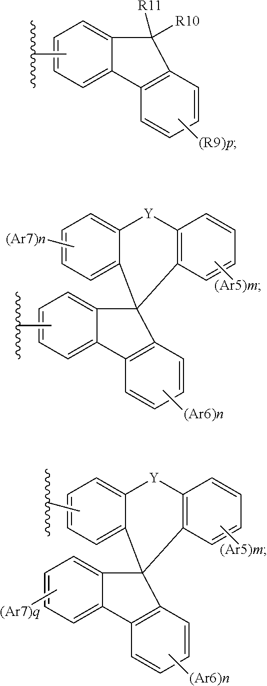

in which:
Ar5, Ar6, and Ar7 are independently selected from: hydrogen, substituted or unsubstituted alkyl having 1 to 20 carbon atoms, substituted or unsubstituted cycloalkyl having 3 to 20 carbon atoms, substituted or unsubstituted silyl having 1 to 20 carbon atoms, and the aromatic or heteroaromatic ring system having 5 to 30 aromatic ring atoms;
p is an integer from 0 to 4; q is an integer from 0 to 4; m is an integer from 0 to 4; n is an integer from 0 to 4;
Y is C, O, S, N or a single bond.

Optionally, at least two of p, m and n are greater than 0, and at least two of (Ar5)p, (Ar6)q, and (Ar7)m are the same, or any two of (Ar5)p, (Ar6)q, and (Ar7)m are different.

Optionally, two adjacent substituents of (Ar5)p, (Ar6)q, and (Ar7)m are bonded to form a ring.

Optionally, the electron transport layer material is selected from:

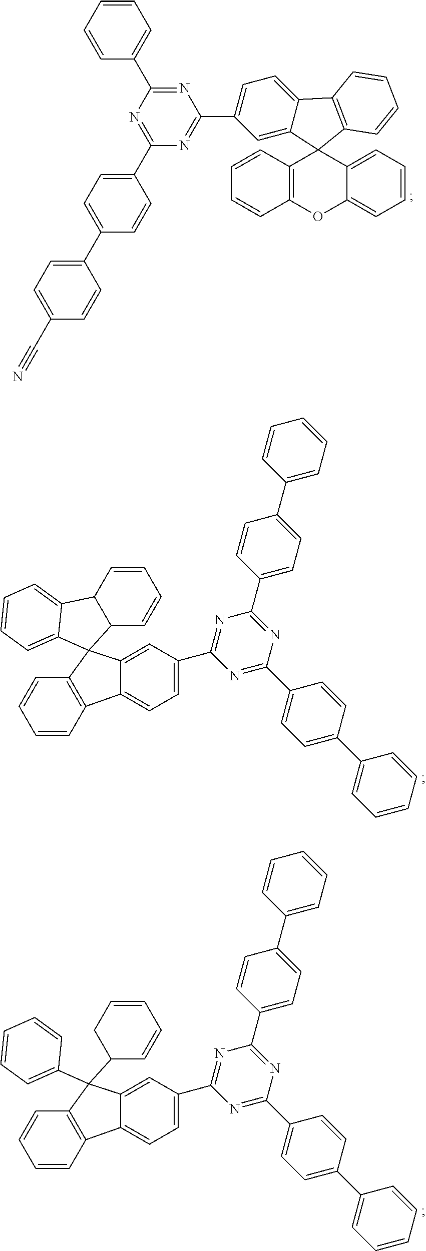 [SMILES: N#Cc1ccc(-c2ccc(-c3nc(-c4ccccc4)nc(-c4ccc5c(c4)C4(c6ccccc6Oc6ccccc64)c4ccccc4-5)n3)cc2)cc1 ; C1=CC2c3ccccc3C3(c4ccccc4-c4ccc(-c5nc(-c6ccc(-c7ccccc7)cc6)nc(-c6ccc(-c7ccccc7)cc6)n5)cc43)C2C=C1 ; C1=CCC(C2(c3ccccc3)c3ccccc3-c3ccc(-c4nc(-c5ccc(-c6ccccc6)cc5)nc(-c5ccc(-c6ccccc6)cc5)n4)cc32)C=C1]

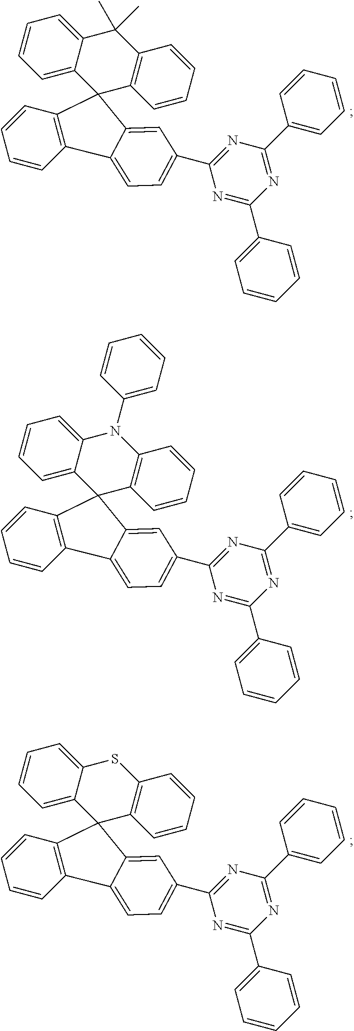 [SMILES: CC1(C)c2ccccc2C2(c3ccccc3-c3ccc(-c4nc(-c5ccccc5)nc(-c5ccccc5)n4)cc32)c2ccccc21 ; c1ccc(-c2nc(-c3ccccc3)nc(-c3ccc4c(c3)C3(c5ccccc5-4)c4ccccc4N(c4ccccc4)c4ccccc43)n2)cc1 ; c1ccc(-c2nc(-c3ccccc3)nc(-c3ccc4c(c3)C3(c5ccccc5Sc5ccccc53)c3ccccc3-4)n2)cc1]

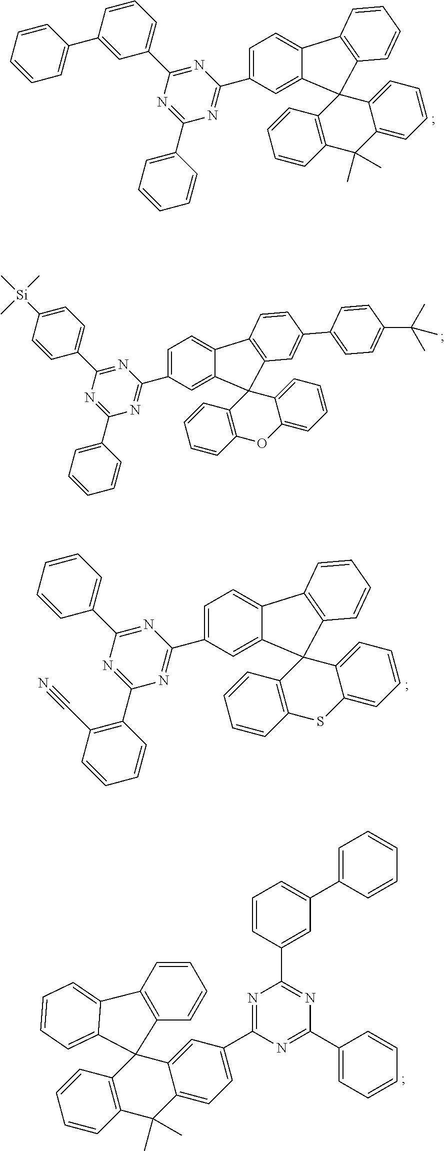 [SMILES: CC1(C)c2ccccc2C2(c3ccccc3-c3ccc(-c4nc(-c5ccccc5)nc(-c5cccc(-c6ccccc6)c5)n4)cc32)c2ccccc21 ; CC(C)(C)c1ccc(-c2ccc3c(c2)C2(c4ccccc4Oc4ccccc42)c2cc(-c4nc(-c5ccccc5)nc(-c5ccc([Si](C)(C)C)cc5)n4)ccc2-3)cc1 ; N#Cc1ccccc1-c1nc(-c2ccccc2)nc(-c2ccc3c(c2)C2(c4ccccc4Sc4ccccc42)c2ccccc2-3)n1 ; CC1(C)c2ccccc2C2(c3ccccc3-c3ccccc32)c2cc(-c3nc(-c4ccccc4)nc(-c4cccc(-c5ccccc5)c4)n3)ccc21]

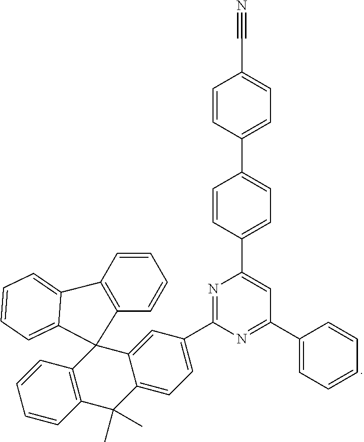 [SMILES: CC1(C)c2ccccc2C2(c3ccccc3-c3ccccc32)c2cc(-c3nc(-c4ccccc4)cc(-c4ccc(-c5ccc(C#N)cc5)cc4)n3)ccc21]

In a second aspect, an embodiment of the present disclosure provides a display device including the organic light-emitting diode structure according to any one of the first aspect.

In this way, the light-emitting layer, the hole blocking layer and the electron blocking layer in the organic light-emitting diode structure provided by the embodiments of the present disclosure satisfy the following conditions: T1(HBL)>T1(Host); T1(EBL)>T1(Host); T1(Dopant)>T1(Host); S1(Host)>S1(Dopant); in which, T1 (HBL) is the lowest triplet energy of the hole blocking layer material, T1 (Host) is the lowest triplet energy of the host material, T1 (EBL) is the lowest triplet energy of the electron blocking layer material, T1 (Dopant) is the lowest triplet energy of the guest material, S1 (Host) is the lowest singlet energy of the host material, and S1 (Dopant) is the lowest singlet energy of the guest material. By controlling the energy level relationship of the light-emitting layer, the hole blocking layer and the electron blocking layer, the carrier accumulation at the interface of the electron blocking layer can be reduced. In addition, it also helps to confine the excitons in the light-emitting layer, preventing the energy of the light-emitting layer from diffusing to other structures. By limiting the energy levels of the host material and the guest material, the excitons in the host material can be made to produce triplet-triplet annihilation, and the energy can be effectively transferred to the guest material. In this way, the technical solution of this embodiment helps to improve the luminous efficiency and lifespan of the display device.

### BRIEF DESCRIPTION OF THE DRAWINGS

In order to illustrate the technical solutions of embodiments of the present disclosure more clearly, the drawings that are required to be used in the description of the embodiments of the present disclosure will be briefly introduced below. Obviously, the drawings in the following description are only some embodiments of the present disclosure, and for those of ordinary skill in the art, other drawings can also be obtained from these drawings without creative effort.

FIG. 1 is a structural schematic view showing the organic light-emitting diode structure according to the first embodiment of the present disclosure.

### DETAILED DESCRIPTION

The technical solutions in the embodiments of the present disclosure will be clearly and completely described below with reference to the drawings in the embodiments of the present disclosure. Obviously, the described embodiments are part of the embodiments of the present disclosure, but not all of the embodiments. Based on the embodiments in the present disclosure, all other embodiments obtained by those of ordinary skill in the art without creative efforts shall fall within the protection scope of the present disclosure.

Embodiments of the present disclosure provide an organic light-emitting diode structure.

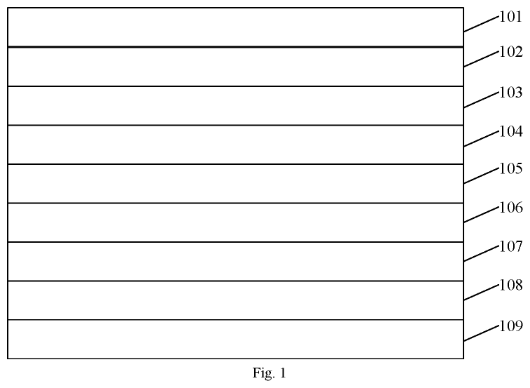

As shown in FIG. 1, in one embodiment, the organic light-emitting diode structure includes the cathode 101, the electron injection layer (EIL) 102, the electron transport layer (ETL) 103, the hole blocking layer (HBL) 104, the light-emitting layer 105, the electron blocking layer (EBL) 106, the hole transport layer (HTL) 107, the hole injection layer (HIL) 108 and the anode 109 are stacked in sequence, and the light-emitting layer 105 includes a host material and a guest material.

The inventors of the present disclosure found in the research process that organic light-emitting diodes (OLED) can be divided into two types: fluorescent OLED light-emitting devices and phosphorescent OLED light-emitting devices. During operation, when a voltage is applied, holes are injected from the anode and electrons are injected from the cathode. Holes and electrons recombine in the light-emitting layer to form excitons. According to the electron spin statistics theory, singlet excitons and triplet excitons are generated in a ratio of 25%:75%. In fluorescent devices emitting light from singlet excitons, the limit value of the internal quantum efficiency is considered to be 25%, as shown in FIG. 1, which corresponds to an external quantum efficiency of about 5%, resulting in lower practical luminous efficiency.

After further research, the inventor found that during the working process, the transmission rate of electrons and the transmission rate of holes are different. Generally speaking, the transport rate of electrons is greater than that of holes, so that excitons in the recombination region of the light-emitting layer are more inclined to the electron-blocking layer, especially the interface at which the electron-blocking layer and the light-emitting layer are intersected. This phenomenon, in turn, may lead to the accumulation of electrons on the material of the electron blocking layer, and the charge may cause deterioration of the material, affecting the performance of the light emitting device.

In the disclosed embodiments, the light-emitting layer, the hole blocking layer and the electron blocking layer satisfy the following conditions:
T1 (HBL)>T1 (Host);
T1 (EBL)>T1 (Host);
T1 (Dopant)>T1 (Host);
S1 (Host)>S1 (Dopant);

Among them, T1 (HBL) is the lowest triplet energy of the hole blocking layer material, T1 (Host) is the lowest triplet energy of the host material, T1(EBL) is the lowest triplet energy of the electron blocking layer material, T1 (Dopant) is the lowest triplet energy of the guest material, S1 (Host) is the lowest singlet energy of the host material, and S1 (Dopant) is the lowest singlet energy of the guest material.

In the embodiments of the present disclosure, by controlling the energy levels of the hole blocking layer and the electron blocking layer, the accumulation of carriers at the interface between the electron blocking layer and the light-emitting layer can be reduced, which helps to confine excitons in the light-emitting layer more effectively, and prevents the energy of the light-emitting layer from diffusing to other structures and film layers, thereby helping to improve the service life.

By limiting the energy levels of the host material and the guest material, the excitons in the host material can be made to produce Triple-Triple Annihilation (abbreviated as TTA) which refers to the phenomenon of generating singlet excitons through the collision and fusion of two triplet excitons, can generate more singlet excitons, effectively transfer energy to the guest material, and help to improve the luminous efficiency.

In some of these embodiments, the hole blocking layer and the electron transport layer satisfy the following conditions:

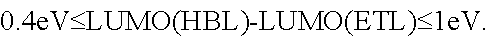

In this embodiment, LUMO represents the lowest unoccupied molecular orbital, LUMO (HBL) is the lowest unoccupied molecular orbital of the hole blocking layer material, and LUMO (ETL) is the lowest unoccupied molecular orbital of the electron transport layer material. In this way, by increasing the energy level barrier between the hole blocking layer and the electron transport layer in this embodiment, the electron transport rate can be slowed down, reducing the possibility that the exciton recombination region is inclined to the side of the electron blocking layer due to the electron transport rate being greater than the hole transport rate.

In some of these embodiments, the hole transport layer and the electron blocking layer satisfy the following conditions:

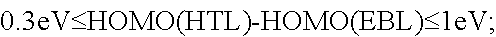

In this embodiment, HOMO represents the highest occupied molecular orbital, HOMO (HTL) is the highest occupied molecular orbital of the hole transport layer, HOMO (EBL) is the highest occupied molecular orbital of the electron blocking layer. In this way, this embodiment can reduce the phenomenon of slow hole transport caused by the energy level barrier, which helps to improve the hole transport rate, thereby, the possibility that the exciton recombination region is inclined to the side of the electron blocking layer due to the hole transport rate being lower than the electron transport rate is reduced.

In some of these embodiments, the host material has a structure of:

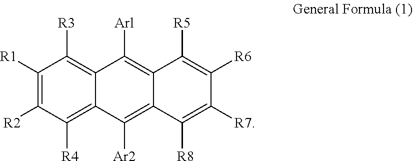

In some of these embodiments, R1, R2, R3, R4, R5, R6, R7 and R8 are each independently selected from: hydrogen atom H, deuterium atom D, substituted or unsubstituted aryl having 6 to 60 carbon atoms, substituted or unsubstituted heteroaryl having 6 to 60 carbon atoms, substituted or unsubstituted alkyl having 1 to 50 carbon atoms, substituted or unsubstituted cycloalkyl having 1 to 50 carbon atoms, substituted or unsubstituted alkoxy having 1 to 50 carbon atoms, substituted or unsubstituted aralkyl having 6 to 50 carbon atoms, substituted or unsubstituted aryloxy having 5 to 50 ring atoms, substituted or unsubstituted arylthio group having 5 to 50 ring atoms, and substituted or unsubstituted alkoxycarbonyl having 1 to 50 carbon atoms.

In this embodiment, any two of R1 to R8 may be the same or different.

In some of the embodiments, among R1, R2, R3, R4, R5, R6, R7, and R8, there are two adjacent substituents bonded to form a ring.

In some of these embodiments, Ar1 is a substituted or unsubstituted aryl.

Substituent Ar2 is selected from any one of the following Ar-1 to Ar-7:

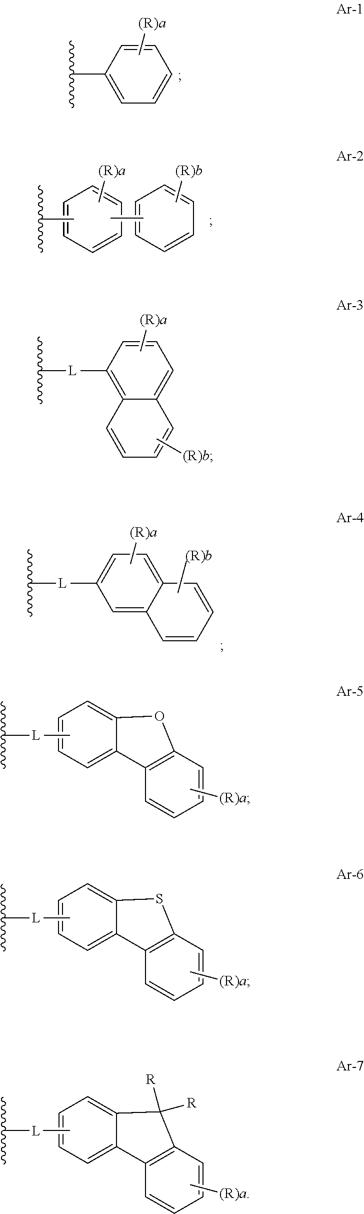

Wherein L is a single bond, a substituted or unsubstituted aryl group; R is a substituted or unsubstituted aryl group, a substituted or unsubstituted heteroaryl group; a is an integer from 0 to 5, and b is an integer from 0 to 5.

In this embodiment, the general formula of the host material represents an anthracene compound, in which the electron cloud of the highest occupied molecular orbital/lowest unoccupied molecular orbital is concentrated on the anthracene nucleus, which can make electrons and holes relatively stable. Further, by introducing groups containing oxygen O and sulfur S on the anthracene nucleus, such as dibenzofuran and other groups, the voltage of the device can be reduced to a certain extent. By introducing groups containing oxygen O and sulfur S in the general formula, the molecule can show a certain polarity, which helps to improve the interaction between the host material and the electron blocking layer, and helps to optimize the energy level of the interface adjacent to the light-emitting layer and the electron blocking layer.

In some of these embodiments, the host material is selected from any ONE of the following Host-1 to Host-6:

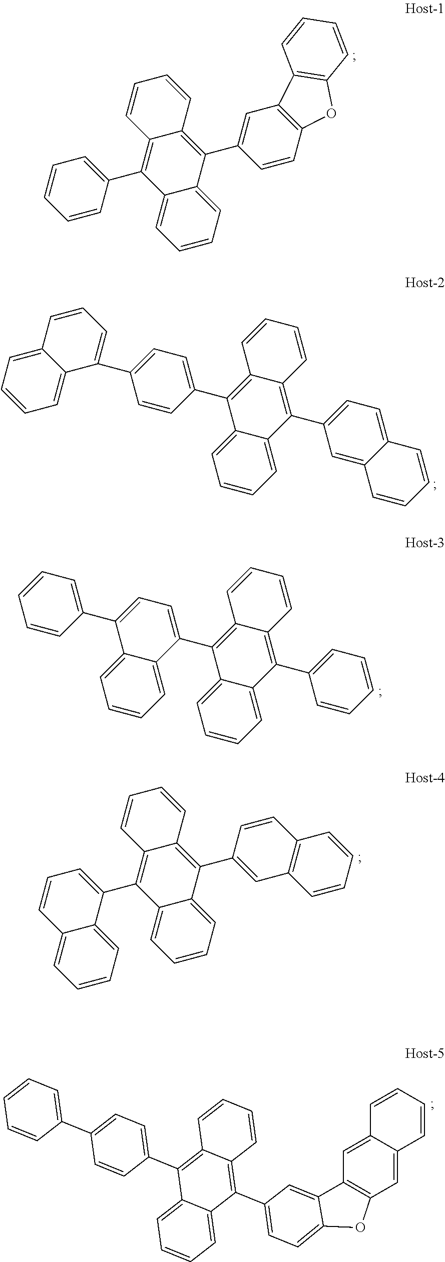

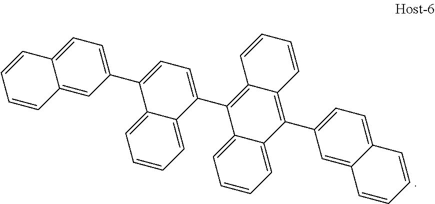 [SMILES: c1ccc2cc(-c3ccc(-c4c5ccccc5c(-c5ccc6ccccc6c5)c5ccccc45)c4ccccc34)ccc2c1]

In some of these embodiments, the material of the electron transport layer has the structure of:

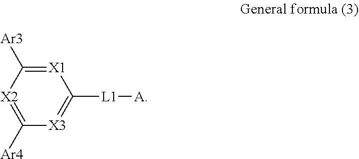

Wherein X1, X2 and X3 are C or N, and at least one of X1, X2 and X3 is nitrogen N.

In some of these embodiments, L1 is a single bond, substituted or unsubstituted C6 to C60 arylene.

Ar3 and Ar4 are substituted or unsubstituted C6 to C60 aryl; or
Ar3 and Ar4 are substituted or unsubstituted C2 to C60 heteroaryl containing at least one of oxygen O, nitrogen N, silicon Si and sulfur S.

Ar3 and Ar4 are the same or different.

In some of these embodiments, the structure of A is selected from any one of the following A-1 to A-3:

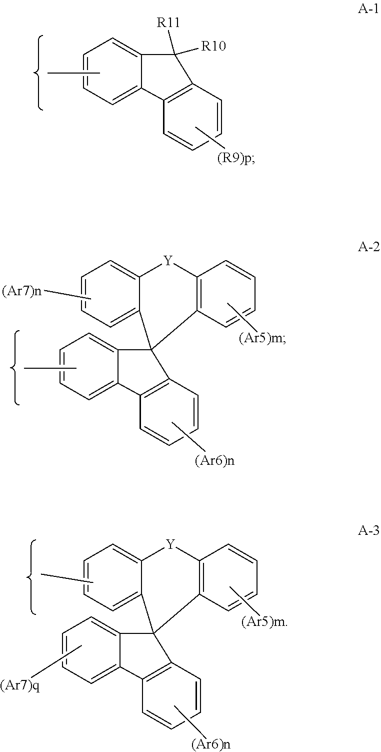

In this embodiment, Ar5, Ar6, Ar7 are independently selected from: hydrogen H, substituted or unsubstituted alkyl having 1 to 20 carbon atoms, substituted or unsubstituted cycloalkyl having 3 to 20 carbon atoms, substituted or unsubstituted silyl having 1 to 20 carbon atoms, and the aromatic or heteroaromatic ring system having 5 to 30 aromatic ring atoms. Wherein p is an integer from 0 to 4; q is an integer from 0 to 4; m is an integer from 0 to 4; n is an integer from 0 to 4; Y is carbon C, oxygen O, sulfur S, nitrogen N or a single bond.

In some of these embodiments, when at least two of p, m and n are greater than 0, at least two of (Ar5)p, (Ar6)q, and (Ar7)m are the same, or any two of (Ar5)p, (Ar6)q, and (Ar7)m are different.

In some of the embodiments, two adjacent substituents of (Ar5)p, (Ar6)q, and (Ar7)m are bonded to form a ring.

In the material of the electron transport layer of this embodiment, the nitrogen-containing azine is a strong electron-withdrawing group, the material of the electron transport layer with such substituents has a deep HOMO/LUMO energy level, which facilitates the transport of charges.

The spiro ring structure is a segment with a higher T1 energy level, which can effectively confine the excitons to the higher T1 of the light-emitting layer, more specifically, to be mainly determined by T1 of the segment; in addition, the spiro ring is a group with better steric configuration and larger steric hindrance, which can inhibit the crystallization of the material to a certain extent.

In some of these embodiments, the material of the electron transport layer is selected from any one of the following ETL-1 to ETL-11:

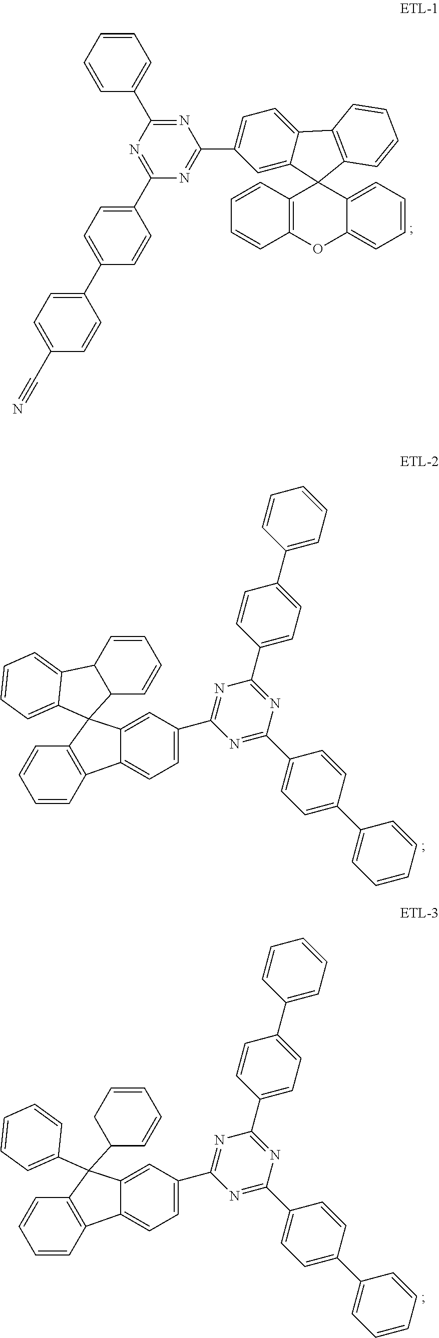 [SMILES: N#Cc1ccc(-c2ccc(-c3nc(-c4ccccc4)nc(-c4ccc5c(c4)C4(c6ccccc6Oc6ccccc64)c4ccccc4-5)n3)cc2)cc1 ; C1=CC2c3ccccc3C3(c4ccccc4-c4ccc(-c5nc(-c6ccc(-c7ccccc7)cc6)nc(-c6ccc(-c7ccccc7)cc6)n5)cc43)C2C=C1 ; C1=CCC(C2(c3ccccc3)c3ccccc3-c3ccc(-c4nc(-c5ccc(-c6ccccc6)cc5)nc(-c5ccc(-c6ccccc6)cc5)n4)cc32)C=C1]

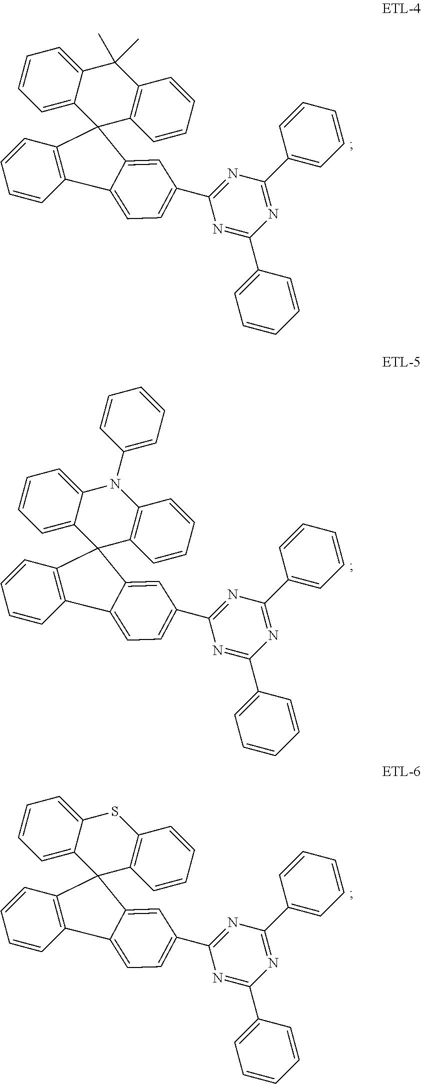 [SMILES: CC1(C)c2ccccc2C2(c3ccccc3-c3ccc(-c4nc(-c5ccccc5)nc(-c5ccccc5)n4)cc32)c2ccccc21 ; c1ccc(-c2nc(-c3ccccc3)nc(-c3ccc4c(c3)C3(c5ccccc5-4)c4ccccc4N(c4ccccc4)c4ccccc43)n2)cc1 ; c1ccc(-c2nc(-c3ccccc3)nc(-c3ccc4c(c3)C3(c5ccccc5Sc5ccccc53)c3ccccc3-4)n2)cc1]

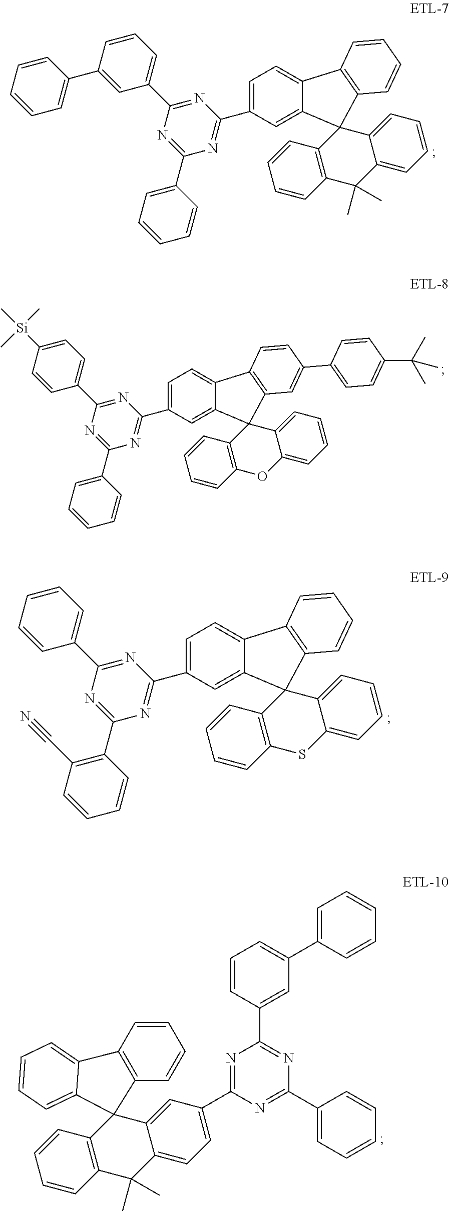 [SMILES: CC1(C)c2ccccc2C2(c3ccccc3-c3ccc(-c4nc(-c5ccccc5)nc(-c5cccc(-c6ccccc6)c5)n4)cc32)c2ccccc21 ; CC(C)(C)c1ccc(-c2ccc3c(c2)C2(c4ccccc4Oc4ccccc42)c2cc(-c4nc(-c5ccccc5)nc(-c5ccc([Si](C)(C)C)cc5)n4)ccc2-3)cc1 ; N#Cc1ccccc1-c1nc(-c2ccccc2)nc(-c2ccc3c(c2)C2(c4ccccc4Sc4ccccc42)c2ccccc2-3)n1 ; CC1(C)c2ccccc2C2(c3ccccc3-c3ccccc32)c2cc(-c3nc(-c4ccccc4)nc(-c4cccc(-c5ccccc5)c4)n3)ccc21]

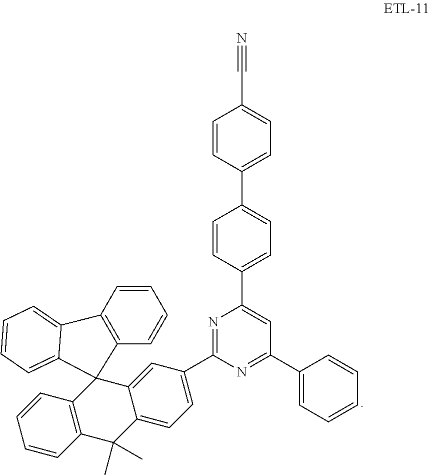 [SMILES: CC1(C)c2ccccc2C2(c3ccccc3-c3ccccc32)c2cc(-c3nc(-c4ccccc4)cc(-c4ccc(-c5ccc(C#N)cc5)cc4)n3)ccc21]

In this embodiment, the mobility of the hole blocking layer is smaller than that of the electron transport layer, so as to slow down the electron transport speed.

In some embodiments, the electron mobility of the hole blocking layer is controlled to be in the ranges from 10⁻⁷ to 10⁻⁹ cm² V⁻¹ s⁻¹, and the electron mobility of the electron transport layer is controlled to be in the ranges from 10⁻⁵ to 10⁻⁷ cm² V⁻¹ s⁻¹, in this way, the transport efficiency of electrons can be inhibited to some extent. The hole mobility of the hole transport layer is in the ranges from 10⁻⁴ to 10⁻⁶ cm² V⁻¹ s⁻¹, and the hole mobility of the electron blocking layer is in the range from 10⁻⁴ to 10⁻⁷ cm² V⁻¹ s⁻¹, thereby improving hole transport efficiency. The electron mobility of the host material of the light-emitting layer is controlled from 10⁻⁵ to 10⁻⁸ cm² V⁻¹ s⁻¹, the hole mobility is controlled from 10⁻⁸ to 10⁻¹² cm² V⁻¹ s⁻¹, which helps to increase the hole-electron transport speed and inhibit the electron transport speed.

An embodiment of the present disclosure provides a display device including any one of the organic light-emitting diode structures above.

Since the display device of this embodiment includes all the technical solutions of embodiments of the above organic light-emitting diode structure, at least all the above technical effects can be achieved, which will not be repeated here.

Hereinafter, the present disclosure will be further exemplified with reference to specific embodiments.

As shown in FIG. 1, in one embodiment, the organic light-emitting diode has a structure including the cathode 101, the electron injection layer (EIL) 102, the electron transport layer (ETL) 103, the hole blocking layer (HBL) 104, the light-emitting layer 105, the electron blocking layer (EBL) 106, the hole transport layer (HTL) 107, the hole injection layer (HIL) 108 and the anode 109 which are stacked in sequence, wherein the light-emitting layer 105 includes a host material and a guest material.

In the embodiment of the present disclosure, the material of the electron injection layer can be selected from metal or alkali metal, such as lithium fluoride LiF, ytterbium Yb, LIQ (C₉H₆NOLi, 8-hydroxyquinoline-lithium) and other materials.

The material of the electron transport layer in the related art is usually an aromatic heterocyclic compound, TPBi, Bphen and other materials, and the material of the above general formula (3) is specifically used in this embodiment.

The material of the hole blocking layer is usually an aromatic heterocyclic compound, such as BCP, Bphen and other materials.

In this embodiment, the host material of the light-emitting layer can be selected from the above-mentioned general formula (1), and the guest material can be selected from Dpvbi, DPAVB, DSA-Ph and other materials.

The material of the electron blocking layer can be selected from aromatic amines or carbazole materials with hole transport properties, such as mCBP, Tris-PCz and other materials.

The material of the hole transport layer can be selected from aromatic amines or carbazole materials with hole transport properties, such as NPB, m-MTDATA, TPD and other materials.

The material of the hole injection layer can be inorganic oxide, such as molybdenum trioxide MoO₃, F4-TCNQ, HAT-CN and other materials.

In the embodiments and comparative examples of the present disclosure, the P-type dopant material of the hole injection layer is:

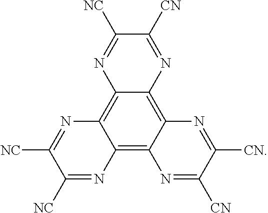 [SMILES: N#Cc1nc2c3nc(C#N)c(C#N)nc3c3nc(C#N)c(C#N)nc3c2nc1C#N]

In the embodiments and comparative examples of the present disclosure, the material of the hole injection layer is:

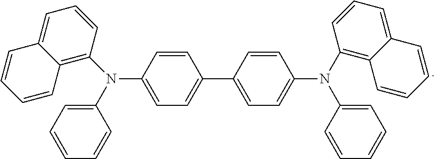 [SMILES: c1ccc(N(c2ccc(-c3ccc(N(c4ccccc4)c4cccc5ccccc45)cc3)cc2)c2cccc3ccccc23)cc1]

In the embodiments and comparative examples of the present disclosure, the material of the electron blocking layer is:

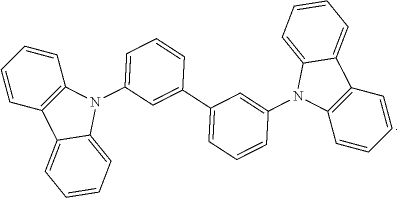 [SMILES: c1cc(-c2cccc(-n3c4ccccc4c4ccccc43)c2)cc(-n2c3ccccc3c3ccccc32)c1]

In the comparative example, the electron transport layer material can be the comparative ETL:

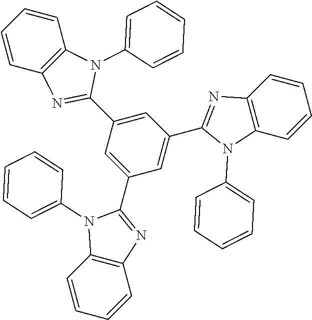 [SMILES: c1ccc(-n2c(-c3cc(-c4nc5ccccc5n4-c4ccccc4)cc(-c4nc5ccccc5n4-c4ccccc4)c3)nc3ccccc32)cc1]

In the embodiments and comparative examples of the present disclosure, the material of the hole blocking layer is:

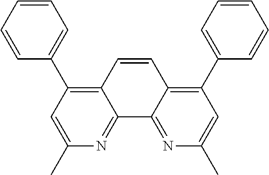 [SMILES: Cc1cc(-c2ccccc2)c2ccc3c(-c4ccccc4)cc(C)nc3c2n1]

The host material of the comparative example can be the comparative Host:

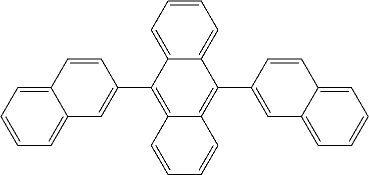 [SMILES: c1ccc2cc(-c3c4ccccc4c(-c4ccc5ccccc5c4)c4ccccc34)ccc2c1]

In the embodiments and comparative examples of the present disclosure, the guest material is:

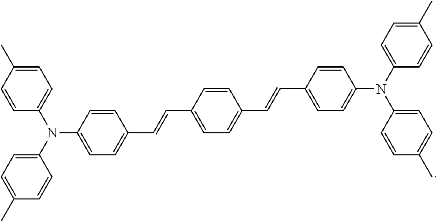 [SMILES: Cc1ccc(N(c2ccc(C)cc2)c2ccc(/C=C/c3ccc(/C=C/c4ccc(N(c5ccc(C)cc5)c5ccc(C)cc5)cc4)cc3)cc2)cc1]

The present disclosure exemplarily provides a number of comparative examples and embodiments.

In comparative example 1, the comparative ETL is selected as the material of the electron transport layer, and the comparative Host is selected as the host material.

In comparative example 2, the above-mentioned ETL-2 is selected as the material of the electron transport layer, and the comparative Host is selected as the host material.

In comparative example 3, the above-mentioned ETL-3 is selected as the material of the electron transport layer, and the comparative Host is selected as the host material.

In comparative example 4, the comparative ETL is selected as the material of the electron transport layer, and the above-mentioned Host-1 is selected as the host material.

In comparative example 5, the comparative ETL is selected as the material of the electron transport layer, and the above-mentioned Host-4 is selected as the host material.

In embodiment 1, the above-mentioned ETL-2 is selected as the material of electron transport layer, and the above-mentioned Host-1 is selected as the host material.

In embodiment 2, the above-mentioned ETL-2 is selected as the material of electron transport layer, and the above-mentioned Host-4 is selected as the host material.

In embodiment 3, the above-mentioned ETL-3 is selected as the material of electron transport layer, and the above-mentioned Host-1 is selected as the host material.

In embodiment 4, the above-mentioned ETL-3 is selected as the material of electron transport layer, and the above-mentioned Host-4 is selected as the host material.

The physical properties of the electron transport layer material used in this embodiment are shown in Table 1, and the physical properties of the host material of the light-emitting layer used are shown in Table 2. Voltage, light-emitting efficiency and lifespan tests were performed on the organic light-emitting diode structures of comparative examples 1 to 5 and embodiments 1 to 4, wherein the lifespan tests were performed according to LT95@1000 nit, and the test results are shown in Table 3.

TABLE 1
The physical properties of the electron transport layer material

| ETL | HOMO (eV) | LUMO (eV) | T1(eV) |
|---|---|---|---|
| ETL-2 | −6.50 | −3.4 | 2.52 |
| ETL-3 | −6.4 | −2.51 | 2.58 |

TABLE 2
The physical properties of the host material

| Host | HOMO | LUMO | T1 |
|---|---|---|---|
| Host-1 | −6.00 | −3.01 | 1.77 |
| Host-4 | −6.01 | −2.98 | 1.71 |

TABLE 3
Test results of comparative examples and embodiments of OLED structure

| | | | | | Lifespan |
|---|---|---|---|---|---|
| | Material combination | | Voltage | Efficiency | (LT95@1000 nit) |
| Comparative | Comparative | Comparative | 100% | 100% | 100% |
| Example 1 | ETL | Host | | | |
| Comparative | ETL-2 | Comparative | 100% | 102% | 118% |
| Example 2 | | Host | | | |
| Comparative | ETL-3 | Comparative | 95% | 105% | 120% |
| Example 3 | | Host | | | |
| Comparative | Comparative | Host-1 | 94% | 113% | 107% |
| Example 4 | ETL | | | | |
| Comparative | Comparative | Host-4 | 97% | 109% | 104% |
| Example 5 | ETL | | | | |
| Embodiment | ETL-2 | Host-1 | 95% | 118% | 125% |
| 1 | | | | | |
| Embodiment | ETL-2 | Host-4 | 95% | 130% | 137% |
| 2 | | | | | |
| Embodiment | ETL-3 | Host-1 | 93% | 115% | 122% |
| 3 | | | | | |
| Embodiment | ETL-3 | Host-4 | 96% | 130% | 129% |
| 4 | | | | | |

It can be seen from the above Tables that by improving the material of the electron transport layer and the host material of the light-emitting layer, the light-emitting efficiency of the light-emitting device is improved and the service life is increased.

The above are only specific embodiments of the present disclosure, but the protection scope of the present disclosure is not limited thereto. Any person skilled in the art can easily conceive of changes or substitutions within the technical scope disclosed by the present disclosure, which should be included within the protection scope of the present disclosure. Therefore, the protection scope of the present disclosure should be host to the protection scope of the claims.

1. An organic light-emitting diode structure, comprising a cathode, an electron transport layer, a hole blocking layer, a light-emitting layer, an electron blocking layer, a hole transport layer and an anode that are stacked in sequence, wherein the light-emitting layer comprises a host material and a guest material;
the host material has a structure of: 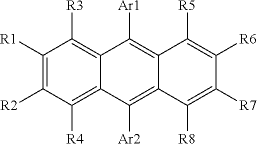
wherein:
R1, R2, R3, R4, R5, R6, R7 and R8 are each independently selected from: hydrogen atom, deuterium atom, substituted or unsubstituted aryl having 6 to 60 carbon atoms, substituted or unsubstituted heteroaryl having 6 to 60 carbon atoms, substituted or unsubstituted alkyl having 1 to 50 carbon atoms, substituted or unsubstituted cycloalkyl having 1 to 50 carbon atoms, substituted or unsubstituted alkoxy having 1 to 50 carbon atoms, substituted or unsubstituted aralkyl having 6 to 50 carbon atoms, substituted or unsubstituted aryloxy having 5 to 50 ring atoms, substituted or unsubstituted arylthio having 5 to 50 ring atoms, and substituted or unsubstituted alkoxycarbonyl having 1 to 50 carbon atoms;
Ar1 is substituted or unsubstituted aryl;
Ar2 is selected from any one of the following: 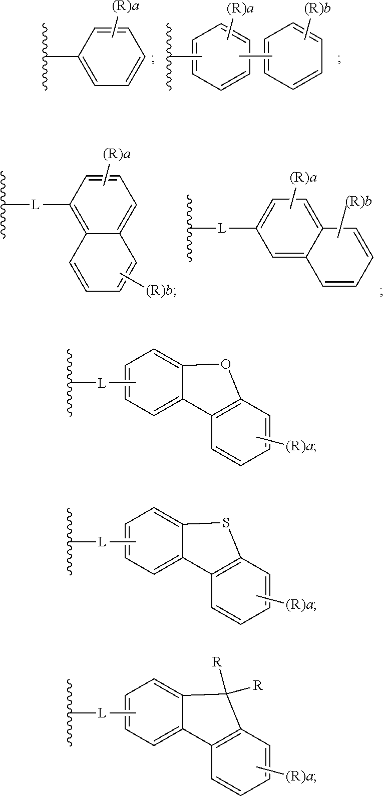
wherein:
L is a single bond, or substituted or unsubstituted aryl;
R is substituted or unsubstituted aryl, substituted or unsubstituted heteroaryl, and a plurality of Rs are the same or different;
a is an integer from 0 to 5, and b is an integer from 0 to 5;
the light-emitting layer, the hole blocking layer and the electron blocking layer satisfy the following conditions: 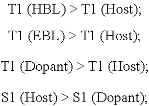
an electron blocking layer material and a hole transport layer material comprise aromatic amine materials or carbazole materials, a hole mobility of the hole transport layer ranges from 10⁻⁴ cm² V⁻¹ s⁻¹ to 10⁻⁶ cm² V⁻¹ s⁻¹, a hole mobility of the electron blocking layer ranges from 10⁻⁴ cm² V⁻¹ s⁻¹ to 107 cm² V⁻¹ s⁻¹,
wherein T1 (HBL) is the lowest triplet energy of a hole blocking layer material, T1 (Host) is the lowest triplet energy of the host material, T1 (EBL) is the lowest triplet energy of the electron blocking layer material, T1 (Dopant) is the lowest triplet energy of the guest material, S1 (Host) is the lowest singlet energy of the host material, and S1 (Dopant) is the lowest singlet energy of the guest material.

2. The organic light-emitting diode structure of claim 1, wherein the hole blocking layer and the electron transport layer satisfy the following conditions: 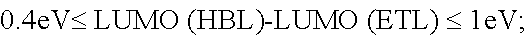
wherein LUMO (HBL) is the lowest unoccupied molecular orbital of the hole blocking layer material, and LUMO (ETL) is the lowest unoccupied molecular orbital of an electron transport layer material.

3. The organic light-emitting diode structure of claim 1, wherein the hole transport layer and the electron blocking layer satisfy the following conditions: 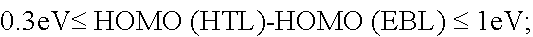
wherein HOMO (HTL) is the highest occupied molecular orbital of the hole transport layer, and HOMO (EBL) is the highest occupied molecular orbital of the electron blocking layer.

4. The organic light-emitting diode structure of claim 1, wherein an electron mobility of the hole blocking layer ranges from 10⁻⁷ cm² V⁻¹ s 1 to 10⁻⁹ cm² V⁻¹ s⁻¹, and an electron mobility of the electron transport layer ranges from 10⁻⁵ cm² V⁻¹ s⁻¹ to 10⁻⁷ cm² V⁻¹ s⁻¹;
an electron mobility of the host material of the light-emitting layer ranges from 10⁻⁵ cm² V⁻¹ s⁻¹ to 10⁻⁸ cm² V⁻¹ s⁻¹, and a hole mobility ranges from 10⁻⁸ cm² V⁻¹ s⁻¹ to 10⁻¹² cm² V⁻¹ s⁻¹.

5. The organic light-emitting diode structure of claim 1, wherein two adjacent substituents of R1, R2, R3, R4, R5, R6, R7 and R8 are bonded to form a ring.

6. The organic light-emitting diode structure of claim 1, wherein two adjacent Rs are bonded to form a ring.

7. The organic light-emitting diode structure of claim 1, wherein the host material is selected from:

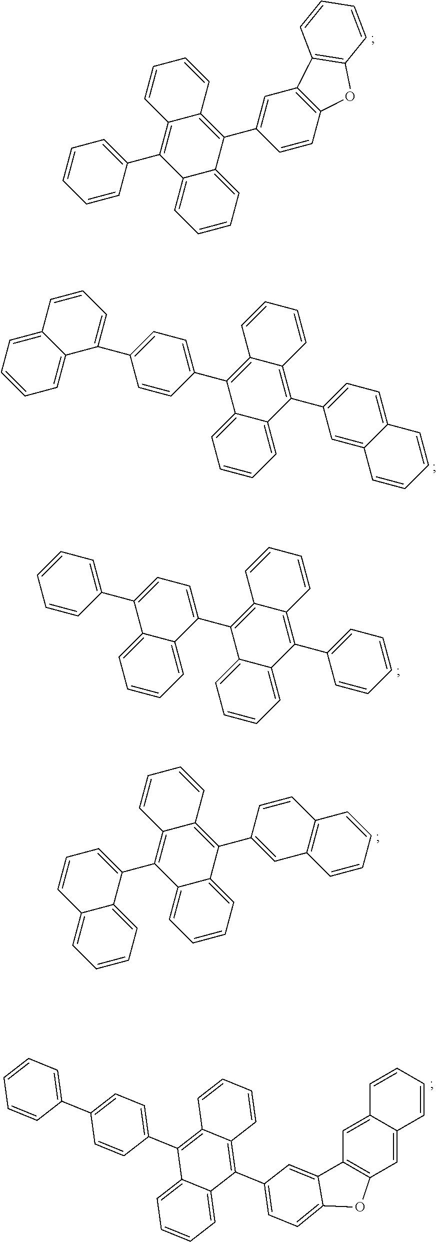

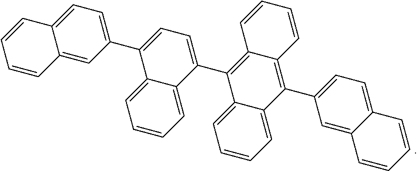 [SMILES: c1ccc2cc(-c3ccc(-c4c5ccccc5c(-c5ccc6ccccc6c5)c5ccccc45)c4ccccc34)ccc2c1]

8. The organic light-emitting diode structure of claim 1, wherein the electron transport layer material has a structure of: 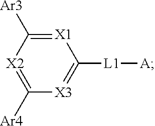
wherein;
X1, X2 and X3 are C or N, and at least one of X1, X2 and X3 is N;
L1 is a single bond, or substituted or unsubstituted C6 to C60 arylene;
Ar3 and Ar4 are substituted or unsubstituted C6 to C60 aryl; or
Ar3 and Ar4 are substituted or unsubstituted C2 to C60 heteroaryl containing at least one of O, N, Si and S;
Ar3 and Ar4 are the same or different;
a structure of A is selected from any one of the following: 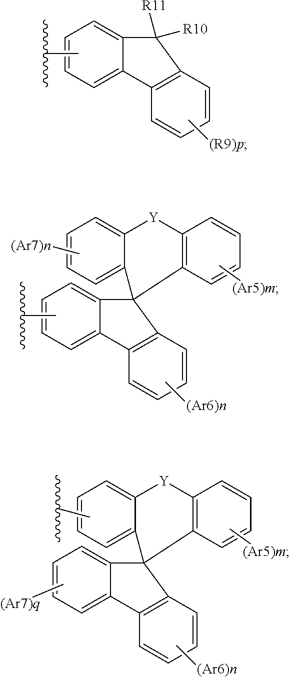
wherein:
Ar5, Ar6, and Ar7 are independently selected from: hydrogen, substituted or unsubstituted alkyl having 1 to 20 carbon atoms, substituted or unsubstituted cycloalkyl having 3 to 20 carbon atoms, substituted or unsubstituted silyl having 1 to 20 carbon atoms, and aromatic or heteroaromatic ring system having 5 to 30 aromatic ring atoms;
p is an integer from 0 to 4; q is an integer from 0 to 4; m is an integer from 0 to 4; n is an integer from 0 to 4;
Y is C, O, S, N or a single bond.

9. The organic light-emitting diode structure of claim 8, wherein at least two of p, m and n are greater than 0, and at least two of (Ar5)p, (Ar6)q, and (Ar7)m are the same, or any two of (Ar5)p, (Ar6)q, and (Ar7)m are different.

10. The organic light-emitting diode structure of claim 9, wherein two adjacent substituents of (Ar5)p, (Ar6)q, and (Ar7)m are bonded to form a ring.

11. The organic light-emitting diode structure of claim 1, wherein the electron transport layer material is selected from:

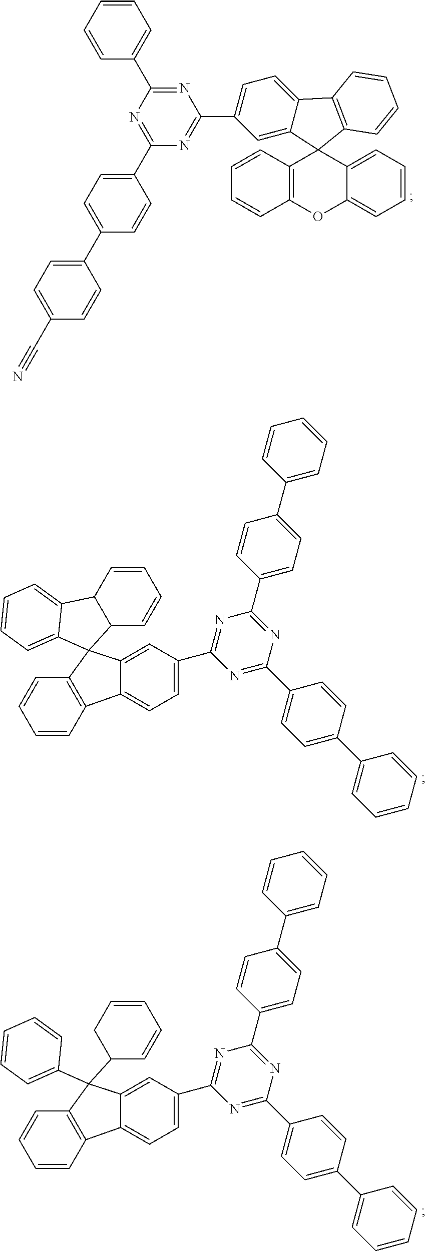 [SMILES: N#Cc1ccc(-c2ccc(-c3nc(-c4ccccc4)nc(-c4ccc5c(c4)C4(c6ccccc6Oc6ccccc64)c4ccccc4-5)n3)cc2)cc1 ; C1=CC2c3ccccc3C3(c4ccccc4-c4ccc(-c5nc(-c6ccc(-c7ccccc7)cc6)nc(-c6ccc(-c7ccccc7)cc6)n5)cc43)C2C=C1 ; C1=CCC(C2(c3ccccc3)c3ccccc3-c3ccc(-c4nc(-c5ccc(-c6ccccc6)cc5)nc(-c5ccc(-c6ccccc6)cc5)n4)cc32)C=C1]

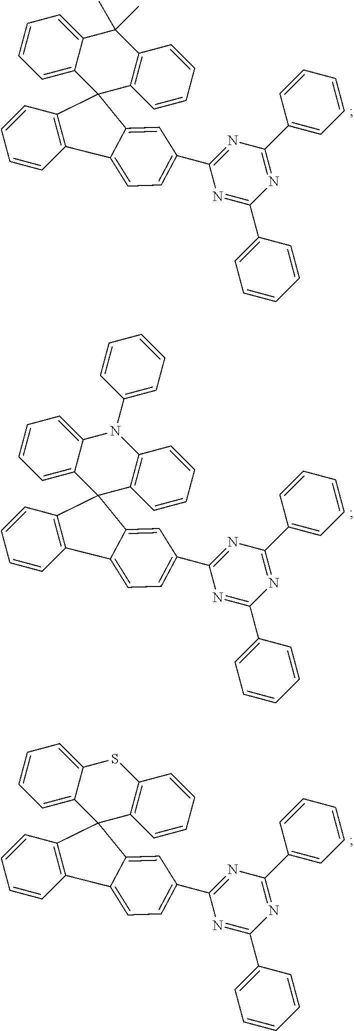 [SMILES: CC1(C)c2ccccc2C2(c3ccccc3-c3ccc(-c4nc(-c5ccccc5)nc(-c5ccccc5)n4)cc32)c2ccccc21 ; c1ccc(-c2nc(-c3ccccc3)nc(-c3ccc4c(c3)C3(c5ccccc5-4)c4ccccc4N(c4ccccc4)c4ccccc43)n2)cc1 ; c1ccc(-c2nc(-c3ccccc3)nc(-c3ccc4c(c3)C3(c5ccccc5Sc5ccccc53)c3ccccc3-4)n2)cc1]

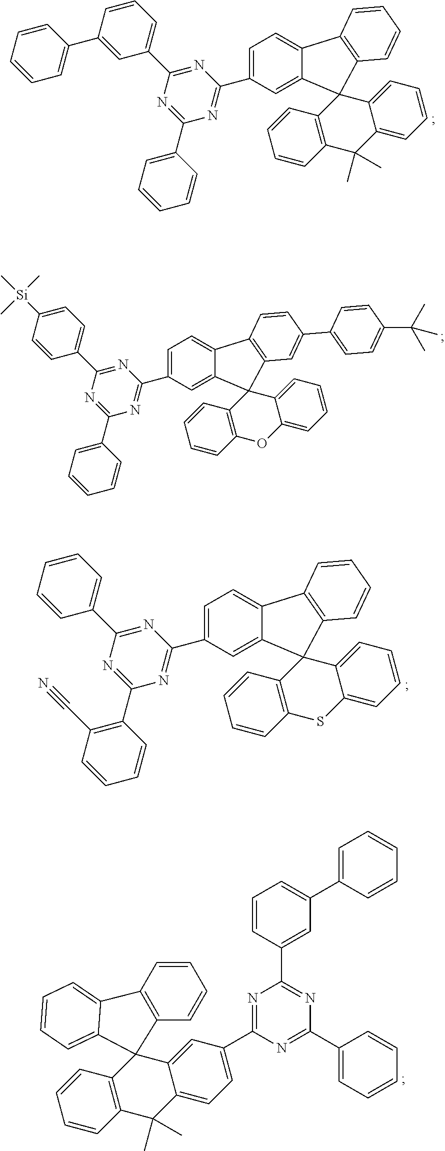 [SMILES: CC1(C)c2ccccc2C2(c3ccccc3-c3ccc(-c4nc(-c5ccccc5)nc(-c5cccc(-c6ccccc6)c5)n4)cc32)c2ccccc21 ; CC(C)(C)c1ccc(-c2ccc3c(c2)C2(c4ccccc4Oc4ccccc42)c2cc(-c4nc(-c5ccccc5)nc(-c5ccc([Si](C)(C)C)cc5)n4)ccc2-3)cc1 ; N#Cc1ccccc1-c1nc(-c2ccccc2)nc(-c2ccc3c(c2)C2(c4ccccc4Sc4ccccc42)c2ccccc2-3)n1 ; CC1(C)c2ccccc2C2(c3ccccc3-c3ccccc32)c2cc(-c3nc(-c4ccccc4)nc(-c4cccc(-c5ccccc5)c4)n3)ccc21]

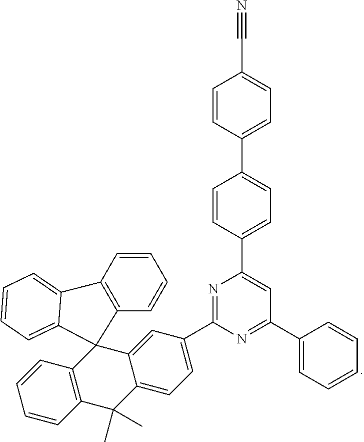 [SMILES: CC1(C)c2ccccc2C2(c3ccccc3-c3ccccc32)c2cc(-c3nc(-c4ccccc4)cc(-c4ccc(-c5ccc(C#N)cc5)cc4)n3)ccc21]

12. A display device, comprising the organic light-emitting diode structure of claim 1.
